(19) United States
(12) Patent Application Publication
(10) Pub. No.: US 2008/0251006 A1
(43) Pub. Date: Oct. 16, 2008

(54) Controlled synthesis of nanoparticles using continuous liquid-flow aerosol method

(75) Inventors: Yuri T. Didenko, Savoy, IL (US); Yuhua Ni, Champaign, IL (US)

Correspondence Address: UT DOTS, INC., 60 HAZELWOOD DR., CHAMPAIGN, IL, 61820, US

(73) Assignee: UT Dots, Inc., Champaign, IL (US)

(21) Appl. No.: 11/734,172

(22) Filed: Apr. 11, 2007

(51) Int. Cl. C30B 7/10

(52) U.S. Cl. 117/3; 117/204

(57) ABSTRACT

A method and apparatus for producing surface stabilized nanometer-sized particles, the method including the steps of forming the aerosol by mixing reactants, a surface-stabilizing surfactant, and a liquid to form a mixture, forming a mist of droplets of the mixture, heating the droplets to cause a reaction between species of the mixture and collecting the nanometer-sized products. The method for producing various size, shape and size distribution of nanoparticles by changing the ratio of the reagents and the ligands in the mixture of precursors.

### FEDERALLY SPONSORED RESEARCH OR DEVELOPMENT

This invention was made with Government support under SBIR Grant award No. OII-0539385 by the National Science Foundation (NSF). The Government has certain rights in the invention.

### CROSS-REFERENCES TO RELATED APPLICATIONS

None.

### FIELD OF THE INVENTION

The present invention relates to methods for controlled production of surface stabilized particles, such as semiconductor nanoparticles, nanooxides and nanometals (also called nanocrystals or quantum dots) and apparatus for such manufacture.

### BACKGROUND OF THE INVENTION

It is anticipated that the future will be the era of nanotechnology. Through nanotechnology, higher quality products can be made by using smaller amounts of materials to achieve the same desired effects. Customers will receive products at lower costs with greater functionality in smaller packages.

Particles with their smallest dimension between 1 to 100 nm have generated great scientific and commercial interest due to their size-dependent properties and potential uses in electronics, fluorescent imaging, medicine, the chemical industry and everyday life. These size-dependent properties are usually observed at particle sizes below ˜20 nm and include the decrease of the material's melting point and a change in the absorbance and/or emission wavelengths depending on the size—quantum size effect. See e.g., Alivisatos, A. P. (1996). “Perspectives on the physical chemistry of semiconductor nanocrystals.” J. Phys. Chem. 100(31): 13226-13239; Eychmuller, A. (2000). “Structure and photophysics of semiconductor nanocrystals.” J. Phys. Chem. B 104(28): 6514-6528; C. B. Murray, C. R. Kagan, M. G. Bawendi (2000). “Synthesis and characterization of monodisperse nanocrystals and close-packed nanocrystal assemblies.” Ann. Rev. Mater. Sci. 30: 545-610; M. Green, P. O'Brien (1999). “Recent advances in the preparation of semiconductors as isolated nanometric particles: new routes to quantum dots.” Chem. Commun.: 2235-2241; T. Trindadae, P. O'Brien, N. L. Pickett (2001). “Nanocrystalline semiconductors: synthesis, properties and perspectives.” Chem. Mater. 13: 3843-3858; K. Grieve, P. Mulvaney, F. Grieser (2000). “Synthesis and electronic properties of semiconductor nanoparticles/quantum dots.” Current Opinion Coll. Interface Sci. 5: 168-172; H. Bönnemann, R. M. Richards (2001). “Nanoscopic metal particles—synthetic methods and potential applications.” Eur. J. Inorg. Chem. 2455-22480.

The decreased melting point can be used, for example, to melt nanosilver at low temperatures for flexible printed circuits. In another example, CdSe nanoparticles with sizes from 2 to 6 nm strongly absorb and emit light that ranges in color from blue to red, depending on the size of particles. Nanoparticles that show quantum size effects or size-dependent properties are usually called quantum dots (QDs, q-dots). They can be used for light emitting diodes (LED), lasers, displays, optical devices, as catalysts etc. See V. L. Colvin, M. C. Schlamp, A. P. Alivisatos (1994). “Light-emitting diodes made from cadmium selenide nanocrystals and a semiconductor polymer.” Nature (London) 370: 354-357), biological fluorescent labels (see M. Bruchez Jr., M. Moronne, P. Gin, S. Weiss, A. P. Alivisatos (1998). “Semiconductor nanocrystals as fluorescent biological labels.” Science (Washington D.C.) 281: 2013-2016; and W. C. W. Chan, S. Nie (1998). “Quantum dots bioconjugates for ultrasensitive nonisotopic detection.” Science (Washington D. C.) 281: 2016-2018), solar cells (see W. U. Huynh, J. J. Dittmer, A. P. Alivisatos (2002). “Hybrid Nanorod-Polymer Solar Cells.” Science (Washington D.C.) 295: 2425-2427; and W. U. Huynh, J. J. Dittmer, W. C. Libby, G. L. Whiting, A. P. Alivisatos (2003). “Controlling the morphology of nanocrystal-polymer composites for solar cells.” Adv. Funct. Mater. 13: 73-79), lasers (see V. I. Klimov, A. A. Mikhilovsky, S. Xu, A. Malko, J. A. Hollingsworth, D. W. McBranch, C. A. Leatherdale, H-J. Eisler, M. G. Bawendi (2000). “Optical gain and stimulated emission in nanocrystal quantum dots.” Science (Washington D.C.) 290: 314-317; and H-J. Eisler, V. C. Sundar, M. G. Bawendi, M. Walsh, H. I. Smith, V. I. Klimov (2002). “Color-selective semiconductor nanocrystal laser.” Appl. Phys. Lett. 80: 4614-4616), and catalysts (see T. R Thurston, J. P. Wicoxon (1999). “Photoxidation of organic chemicals catalyzed by nanoscale MoS₂.” J. Phys. Chem. B. 103: 11-17).

Nanoparticles are finding widespread applications ranging from composites and coatings to cosmetic creams offering ultraviolet radiation protection. According to a Moore and Michelson report (Woodrow Wilson Int. Center for Scholars, April 2006) currently there are ˜212 nanoproducts on the market worldwide. Silver nanoparticles are used as an antibacterial agent in clothing and wound dressing. Nano-oxides are used in the cosmetic industry as sun protection creams, paints, catalysts, in synthetic bones, and as polishing material for silicon wafers. Carbon nanoparticles are used in many commercial products, such as tennis rackets and paint additives. Fluorescent nanoparticles (quantum dots) have commercial applications in bio-labeling, bio-detection, drug delivery and bio-analysis. Future applications of quantum dots include solar cells, lasers, LEDs, flat panel displays, and others. Nanometals can be used as catalysts, in bio-detection, as antibacterial agents and in many other applications.

Currently, colloidal nanoparticles are produced in batch methods on a small scale, which only produces gram-scale quantities, or by using microfluidic reactors which can treat ˜0.3 mL/min of precursor solutions. The current production limitations for these particles lead to a relatively high price. For example, the current price for fluorescent cadmium selenide quantum dots varies from $2,100 (NN-Labs, LLC) to $20,000/g (Aldrich). Among other weaknesses of the current technologies is their inability to generate reproducible results from one batch to another because the reaction rates are rapid, and difficult to control at the necessary high temperatures. Thus, each batch of particles will have slightly different sizes and size distribution. Combining particles from different batches will only broaden the size distribution of the product.

Other approach for the synthesis of nanoparticles is a gas phase reaction which produces nanoparticles at high temperatures in the reactor. The time of reaction is short and the cooling rate is high. Thus, obtained particles do not sinter and have a small size from a few nanometers to hundreds of nanometers in diameter. Oxides and nanometals can be obtained by this procedure. The drawbacks of such processes are the broad size distribution, irregular shape, and aggregation of the primary particles.

Our synthetic procedures differ from traditional aerosol processes. In our procedure, we add surfactants to in the reaction mixture, and the reaction proceeds in small droplets of a high boiling point solvent. The temperature inside the reactor is lower than the boiling point of the solvent, so the reaction proceeds inside the droplets of aerosol. The mechanism of reactions inside the droplets is similar to the mechanism of batch nanoparticle synthesis reactions in small chemical glassware. The synthesized particles are in colloidal form and soluble in organic solvents. The particles do not agglomerate during storage and can stay in soluble form for a long time. The particle quality is higher relative to size, shape, and size distribution, as compared to the quality of particles made by traditional gas-phase reaction methods.

The present invention overcomes the deficiencies in prior patent application using chemical aerosol-flow synthesis to synthesize CdSe of nanometer size (Y. T. Didenko, K. S. Suslick “Controlled chemical aerosol flow synthesis of nanometer-sized particles and other nanometer sized products” U.S. Pat. No. 7,160,489 B2, issued Jan. 9, 2007). In this patent, the mist was created using household ultrasonic humidifier working at high frequency 1.7 MHz and it was not possible to create a mist from high boiling point solvents. Thus the mixture had to be diluted with toluene, a lower boiling point solvent, to ease the transfer of the reaction mixture to the vapor phase. This additional dilution of precursor's solution with low boiling point solvent (toluene) was a prerequisite for mist formation. This dilution decreased the yield and the quality of the quantum dots produced. The size distribution of the quantum dots was broader than desired and a bubbler containing toluene was required to collect nanoparticles produced. Another drawback was that the same solution was sonicated in the same vessel for long period of time to mist all of the precursors' solution mixture. This created possibility of sonochemically driven reactions in some reaction solutions. Thus, the previously patented aerosol synthesis approach was limited to producing nanoparticles of lower quality, and the production rate of nanoparticles was limited.

The size of liquid droplets formed by ultrasonic humidifier used in previous invention (working at 1.7 MHz ultrasound frequency) was small, ˜5 microns. In the current invention, the continuous liquid-flow system produces droplets between 10 and 100 microns in diameter with a most preferable droplet size of 40 microns.

The vertical position of sprayer on top of the furnace and the large size of droplets decrease the residence time of the droplets inside reactor as compared to the previous invention. It was not obvious that the reduced residence time would provide a high yield of high quality nanoparticle product. By controlling the size of the furnace (diameter and length), the liquid and the gas flow through the reactor and the ratio of chemical components in the reaction mixture, it was possible to produce higher quality nanoparticles in wide range of sizes than the previous invention.

This present invention provides new, scalable, and inexpensive method for manufacturing surface stabilized nanoparticles. The nanoparticles are produced using a liquid flow method in which a solution of high boiling point solvent containing precursors is flowing through the vibrating tube, excited by high intensity ultrasound thus allowing continuous production of droplets. The product of chemical reaction is easily collected at the exit of the reactor, since products (nanoparticles) are dissolved in high boiling point solvent which easy condenses at room or well above room temperatures. Thus, the advantages of this approach are: scalable process for producing droplets of high boiling point solvent containing nanoparticle precursors and capping agents, simple method of particle collection and higher quality nanoparticle product than previous processes.

This vertical approach has many advantages, including: full use of precursors from the initial mixture; a flexible production method with the option of changing gas and liquid flow rates independently; a simple collection method: since the nanoparticles are directly confined within the droplets, the droplets and nanoparticles contained within, can be directly trapped in a receiving bottle at the output of the reactor; the mixture will not undergo sonochemical reactions in the ultrasonic cell, because sonication only takes place during the short time of atomization; and it is easy to scale up production yield by using commercial spray sources.

The maximum yield of CdSe nanoparticles from previous production system described in patent application (Y. T. Didenko, K. S. Suslick “Controlled chemical aerosol flow synthesis of nanometer-sized particles and other nanometer sized products” U.S. Pat. No. 7,160,489 B2, issued Jan. 9, 2007) was small, ˜70 mg/hour. The production apparatus using a continuous liquid flow aerosol production technique described in current invention allowed yields a 15-20 increase in production rate, ˜1-1.5 g/hour, and could be further scaled up. The production rate is only limited by the length and diameter of the reactor tube. The resulting quality of the quantum dots produced is also very good, as indicated by transmission electron microscopy, as well as absorbance and emission measurements. Absorbance and emission are well-known indicators of quantum dot quality. Thus, the quality of quantum dots can be an indication of the performance of the method. The CdSe nanoparticles produced have a fluorescence quantum yield (QY) ˜40-50%, with full width at the half maximum (FWHM) ˜28-30 nm, and our CdTe q-dots have QY ˜40% with FWHM ˜30 nm. These are very good numbers and comparable to the best quantum dots published in literature.

The market for colloidal nanoparticles (quantum dots) is currently ˜$10 million and is growing at a rapid pace. The current sales of quantum dots are in the kilogram range. However, future applications for QDs are projected to expand significantly. It is expected that numerous new applications for quantum dots in biomedicine, solar cells, and electronic components (e.g. optical displays) will appear within a few years. Thus, sales will quickly grow to $500 million in 2009 with anticipated price of $500 per kilo with total sales of 1,000 tons. This expanding market has the potential to dramatically increase the need for quantum dots. The applications of quantum dots are under development in many companies, and we expect revolutionary changes in a few years. The described herein production method is scalable and will satisfy the needs of industry for future applications.

The anticipated advances in q-dots applications will require large quantities of inexpensive materials. Currently, the limited number of high-priced nanomaterials products on the market hinders the development of new devices, methods and products. In the future, with improved production methods, the price should drop from thousands of dollars per gram to hundreds of dollars per gram. New applications of quantum dots and new companies based on these applications emerge every day. The demand for nanoparticles is urgent and will accelerate in the next few years. It is imperative to satisfy these demands by creating a technology that will produce high quality quantum dots in the most inexpensive way.

### SUMMARY OF THE INVENTION

This invention is focused on the synthesis of surface stabilized nanoparticles from an aerosol of a high boiling point solvent. In a traditional spray pyrolysis method, aerosol generator creates droplets from a solution containing selected precursors that are subsequently carried by an appropriate (inert or reactive) gas into a simple tube furnace. As the droplets pass through the reactor, solvent evaporates and the dissolved substances react, precipitate, or decompose to form a uniform spherical powder carried by the gas stream. Ultrasound spray pyrolysis (USP) is a variant of spray pyrolysis methods. A major advantage of USP is that each droplet, and consequently each particle formed, is subjected to the same reaction conditions. Thus, the chemical and phase compositions of all particles are the same. The particles may be trapped in a liquid, or may be used to coat a solid surface.

One of the main differences between traditional USP techniques and the invention described here is that in this invention the reaction mixture consists of high boiling point solvents containing surface active agents, which stabilize particles during their growth and chemical reactions. The temperature of the furnace tube is lower than the boiling point of the solvent, so the solvent does not significantly evaporate; and the synthesis reaction thus proceeds in small droplets of this high boiling point solvent. We call this method a chemical aerosol-flow synthesis, or CAFS.

The CAFS method has many advantages. The synthesis proceeds in isolated micro-scale reactors (i.e., liquid droplets) carried in a gas phase at a controlled temperature. The temperature is selected for the specific nanoparticle synthesis reaction. Most preferably a high boiling point solvent is used, and the reaction temperature is elevated above room temperature. The reaction zone is separated from the initial solution, which is kept at a lower temperature than the temperature of the reaction zone. Nanocrystals can be obtained in any desired quantity with high quality and reproducibility once the parameters of the procedure are established. The obtained nanoparticles can be easily deposited on desired surfaces or collected at low temperatures in desired solvent.

At present, ultrasonic horn atomizers (Sono-Tek Co. and others) are used to produce the mist from high boiling point solvents. These atomizers work at ultrasound frequency (60 kHz) and are capable of producing mists from high boiling point and viscous solvents. These atomizers work in the flow regime, which allows delivery of the mixture directly to the heating zone. We use a sprayer in the vertical position, directly on the top of the heating zone, similar to spray-drying techniques (FIG. 1). Other sprayers however can be used in any other position depending on the configuration of setup needed.

The process described herein can be used to synthesize a wide range of nanomaterials, including semiconductor nanoparticles, nanometals, nanooxides and their composites. Precursors for the manufacture of such products in accordance with the present invention include cadmium, zinc, silver, copper, molybdenum and other metal precursors, chalcogenide (e.g., sulfur, selenium, and tellurium) precursors, and metal salts as metal and oxide precursors.

In accordance with the present invention, chemical reactions occur in aerosol. The reaction proceeds inside tiny liquid droplets, containing reactants and a surface stabilizer or surfactant.

The size, quality, and the yield of nanoparticles can be controlled by the temperature of hot-wall reactor, by the residence time of the reactants inside the reactor, by the length of the reactor and by the ratio of surfactants or the ratio of surfactant to precursor concentrations.

### BRIEF DESCRIPTION OF THE DRAWINGS

FIG. 1 illustrates an apparatus for chemical aerosol flow synthesis in accordance with a preferred embodiment of the present invention.

FIG. 2 illustrates the effect of the liquid and the gas flow rates through the aerosol generator on the absorbance of CdSe quantum dots for reactor tubes 90 and 150 cm in length. Longer reactor gives better quality quantum dots as judged by the absorbance (narrower absorbance reflects better size distribution).

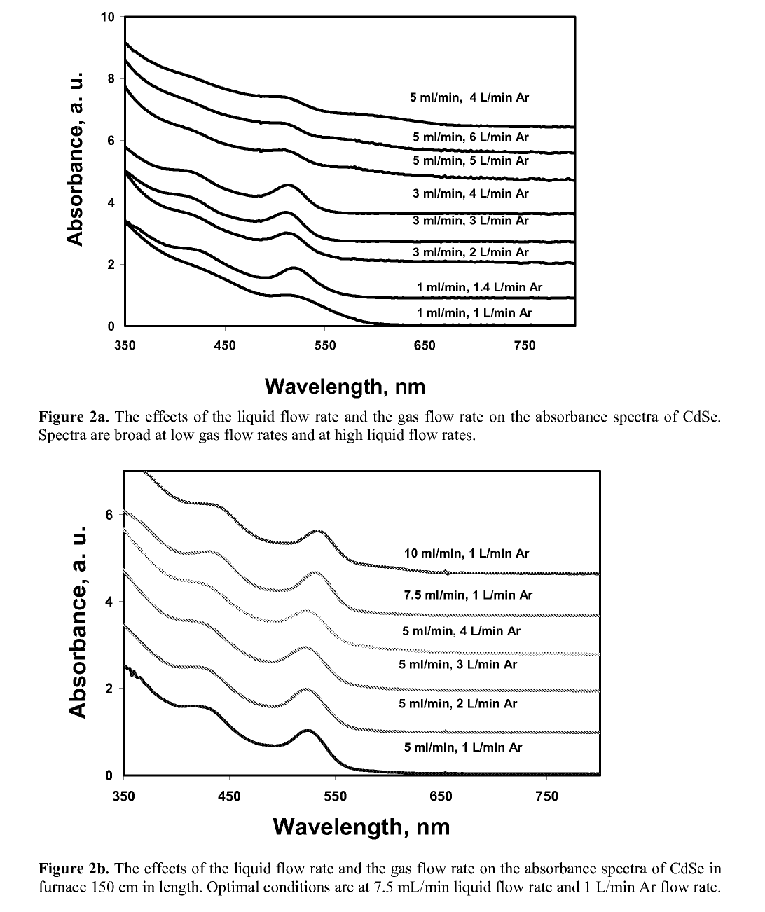

FIG. 3 illustrate absorbance and fluorescence emission spectra of CdSe/oleylamine nanoparticles obtained by aerosol synthesis at 300 degrees Celsius at different diameters of the aerosol reactor. As shown in FIG. 3, the absorption peak became broader with the increase of the liquid flow rate when 30 mm ID reactor was used. Thus it is not feasible to get a narrow size distribution of quantum dot using 30 mm ID reactor at higher than 5 ml/min liquid flow rate.

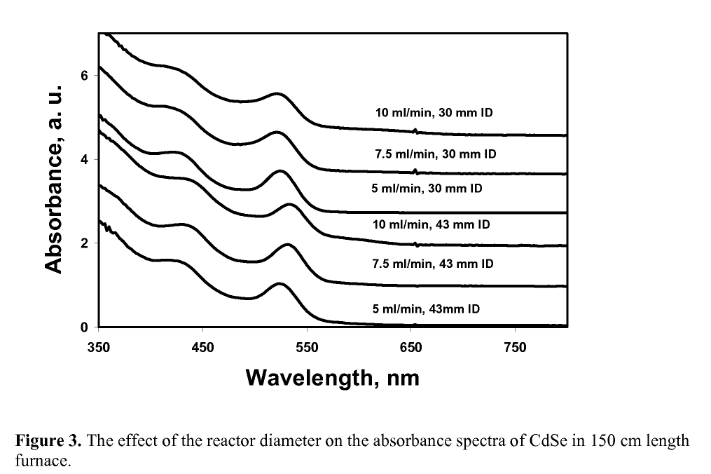

FIG. 4 illustrate XRD and TEM of CdSe/oleylamine nanoparticles obtained from aerosol in accordance with the present invention.

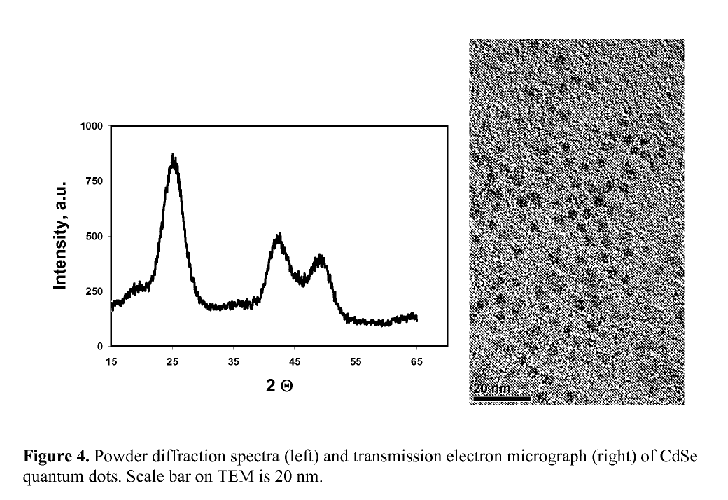

FIG. 5 illustrates CdSe fluorescence of quantum dots obtained by aerosol method in accordance with present invention using a mixture of cadmium naphthenate, TOPSe, oleic acid and oleylamine at 300 degrees Celsius using different lengths and diameters of furnace; and the ratios of surfactants, oleylamine and oleic acid.

### DETAILED DESCRIPTION OF THE PREFERRED EMBODIMENTS

The present invention is related to the scale-up of direct synthesis of nanoparticles from aerosol. The process is continuous, uses inexpensive chemicals and is a preferential method for large scale production of colloidal nanoparticles for future technology needs.

The method is universal for the synthesis of various nanoparticles. Semiconductors, oxides, metal and elemental nanoparticles can be synthesized with high yield and high quality.

The size of nanoparticles can be controlled by adjusting the length of the reactor, furnace temperature, gas, and the liquid flow through the sprayer; by changing the nature of capping agent and the chemical composition of the solution mixture.

Using the process of the present invention, CdSe, silver, copper, nickel, cobalt metal and zinc and iron oxide nanoparticles were produced from organic solvents at high temperature.

The methods of the present invention allow for the continuous and controlled generation of nanometer-sized products of desired size, shape and composition. In accordance with the methods of the present invention, particle sizes can be obtained in the desired 1 to 20 nm region. Larger nanoparticles are also possible to produce.

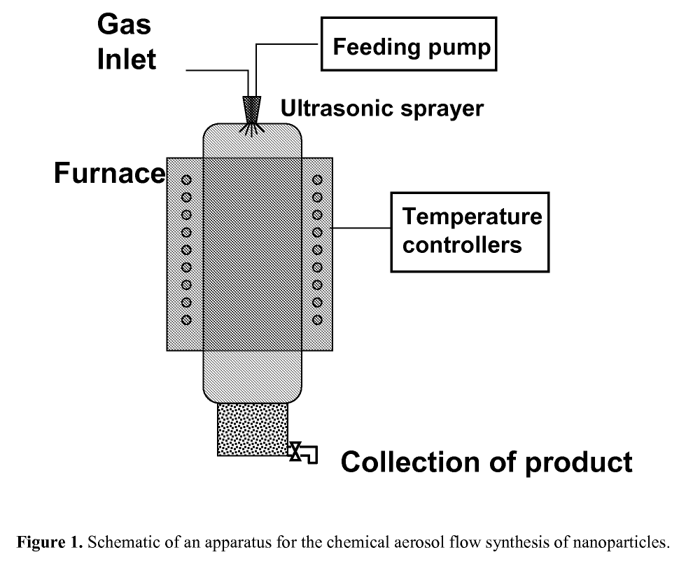

FIG. 1 illustrates an apparatus for synthesis in accordance with a preferred embodiment of the present invention. As shown in FIG. 1, the ultrasonic horn creates droplets of precursors' solution, which are carried through the furnace by a gas (which can be an inert gas or a chemically active gas). For example, an ultrasonic sprayer working at 60 kHz and ˜3 W of acoustic power atomizes a solution into droplets. An example of a suitable aerosol generator is Sono-tek ultrasonic sprayer, Sonics and Materials atomizers and others. The droplets are carried to furnace by an argon stream having a flow rate of 1 to 10 L/min. Particles are collected using a vessel, such as a cooled chemical flask to cool the heated droplets from the heated furnace and condense the droplets containing nanoparticles.

At high temperatures within the reactor tube, the chemical reactions leading to the formation of nanoparticles start taking place. Colloidal nanoparticles are formed inside the droplets and collected at the exit of the reactor.

### EXAMPLES

Synthesis of cadmium chalcogenides from organic solutions can be achieved in accordance with the present invention. One of the first targets was the synthesis of cadmium selenide nanoparticles. The advantage of CdSe nanocrystals over other nanocrystals is that the particle fluorescence covers the whole visible region, so it potentially can be used as light emitting diode, in solar cell or as a multi-wavelength fluorescent probe (See S. Coe, W.-K. Woo, M. Bawendi, V. Bulovic (2002). “Electroluminescence from single monolayers of nanocrystals in molecular organic devices.” Nature, 420: 800-803; I. Gur, N. A. Fromer, M. L. Geier, A. P. Alivisatos (2005). “Air-Stable All-Inorganic Nanocrystal Solar Cells Processed from Solution.” Science, 310: 462-466; D. Larson et al (2003). “Water-soluble quantum dots for multiphoton fluorescence imaging in vivo” Science (Washington D.C.) 300: 1434-1436).

The synthesis of CdSe nanocrystals from organic solutions initially used a mixture of trioctyphosphine selenide, cadmium naphthenate, oleic acid and oleylamine, which were atomized using an ultrasonic sprayer and passed through a furnace tube using the apparatus shown in FIG. 1. The reaction of cadmium and selenium precursors proceeded in small droplets of solvent. By adjusting the temperature of the furnace and the residence time of the droplets in the tube it was possible to get nanocrystals with narrow size distribution and good quality.

The procedure for the synthesis is as follows. The mixture of cadmium and selenium precursors is dissolved in a high boiling point solvent, with the boiling point from about 100 to 400 degree Celsius (e.g., octadecene, trioctylphosphine, trioctylphosphine oxide, trioctylamine, dioctylamine, stearic acid, hexadecylamine, oleic acid, dodecylamine, etc.), containing a substance that serves as a surface stabilizer (e.g., capable of ligation to the particle surface). Examples of suitable stabilizers include trioctylphosphine oxide (TOPO), stearic acid, hexadecylamine, oleic acid, dodecylamine, oleylamine, etc. An aerosol is created using an ultrasonic sprayer (ea Sono-Tek) working at 60 kHz ultrasound frequency. A dense mist is produced and carried by an Ar gas stream to pass through the tube furnace, whose temperature was controlled in the range from 100 to 400° C. At high enough temperatures, the mixture inside this high boiling point liquid droplet starts reacting and forms surfactant-coated nanometer-sized products. More specifically, the species of the first precursor reactant (cadmium) and second precursor reactant (selenium) react inside the high boiling point liquid and form surfactant-coated nanometer-sized products. These nanometer-sized products then exit the tube furnace and are collected in a cooled container. The contained can be a standard spherical glass flask or bubbler made of glass, such as those produced by Chemglass Inc. (of Vineland, N.J.) and other companies.

CdSe nanoparticles obtained by this current invention procedure from the mixture of cadmium naphthenate, trioctylphosphine selenide, oleic acid and oleylamine at 300° C. were highly fluorescent (quantum yield (QY) ˜40%, determined by comparison with the emission from rhodamine 6G) with narrow band emission, full width at half maximum (FWHM) ˜26-30 nm. In accordance with the present invention, these numbers can be improved by changing chemical composition of the mixtures.

For XRD and TEM, samples were purified using hexane/methanol mixture, precipitated with acetone and then redissolved in chloroform or hexane. Absorbance spectra were collected using HP8452A UV-Vis spectrophotometer. Fluorescence spectra were obtained with PTI spectrofluorometer.

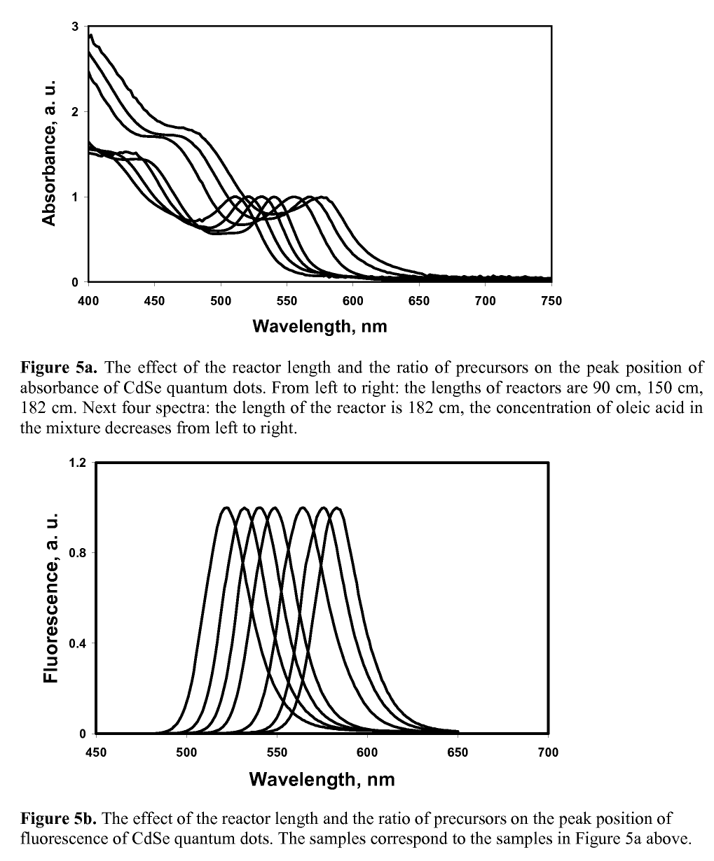

FIG. 5 shows absorbance and fluorescence spectra of nanoparticles so obtained. The reaction mixture is is rather versatile and allows for production of q-dots emitting over a broad spectral region by changing the length of the furnace tube, and by the ratio of oleic acid to oleylamine surfactants.

The size of obtained CdSe quantum dots can be estimated from literature data on the dependence of position of absorbance and fluorescence band vs size. See L. Qu, X. Peng (2001). “Control of photoluminescence properties of CdSe nanocrystals in growth.” J. Am. Chem. Soc. 124: 2049-2055; and A. Striolo, J. Ward, J. M. Prausnitz, W. J. Parak, D. Zanchet, D. Gerion, D. Milliron, A. P. Alivisatos (2002). “Molecular Weight, osmotic second virial coefficient, and extinction coefficient of colloidal nanocrystals.” J. Phys. Chem. B 106: 5500-5505. According to these data, the diameter of CdSe nanoparticles obtained in accordance with the present invention should lie in 2.4-4.0 nm region depending on the conditions of the reaction. This was confirmed by the TEM and XRD results. Fluorescence results are shown in FIG. 5. More specifically, FIG. 5 shows the fluorescence of CdSe nanoparticles obtained by spray pyrolysis at 300° C. and various ratios of surfactants.

Many modifications and variations may be made in the techniques and structures described and illustrated herein without departing from the spirit and scope of the present invention. Accordingly, the techniques and structures described and illustrated herein are illustrative only and not limited to the scope of the present invention.

1. A process for production of nanometer sized particles comprising: a) combining nanocrystals forming reactants, high boiling point solvent and surface stabilizers to form a solution; b) continuously passing said solution through an aerosol generator; c) carrying the formed aerosol using an inert or chemically active gas, possibly containing precursors, through a heating device to cause a reaction between precursors to form nanoparticles; d) collecting the nanoparticles.

2. The process of claim 1, wherein the step of forming an aerosol is performed in a continuous liquid-flow ultrasonic sprayer, compression aerosol generator, or other aerosol generator.

3. The process of claim 1, wherein the step of heating is carried out at 100 to 500° C. in a heated reactor.

4. The process of claim 1, wherein the reaction of synthesis proceeds in small droplets of solvent.

5. The process of claim 1 wherein the reactant mixture consists of two precursor reagents and surfactants or a single precursor reagent and surfactants.

6. The process of claim 1, wherein the precursors solution comprises a cadmium compound, a zinc compound, a molybdenum compound, a copper compound, a silver compound, a gold compound, a tin compound, a lead compound, a sulfur compound, a selenium compound, a tellurium compound and other element compounds.

7. The process of claim 1, wherein the surfactant is selected from the group consisting of trioctylphosphine oxide, stearic acid, oleic acid, oleylamine, hexadecylamine or other amines, acids or combinations of them; and other surfactant.

8. The process of claim 1, wherein the solvent is selected from the group consisting of high boiling point solvent, wherein the high boiling point solvent is selected from the group consisting of alcohols, amines, dimethylformamide, glycol ethers (Glymes), toluene, octadecene, hexadecane, oleic acid, oleylamine, dymethylsulfoxide, and other solvents.

9. Cadmium chalcogenides, zinc chalcogenides, zinc oxide, iron oxide, copper oxide, silver, copper, cobalt, nickel nanoparticles made in accordance with the method of claim 1.

10. An apparatus for producing nanoparticles comprising:
a container with solution of reactants and surfactants to form a reaction mixture;
a pump to deliver the mixture to aerosol generator;
an aerosol generator that forms a mist of droplets of the mixture;
a carrier gas that delivers aerosol from aerosol generator through the heating device to the collector;
a heating device to heat the droplets and to cause a reaction to produce nanoparticles within aerosol;
and a collecting device that collects the nanometer-sized products.

11. The apparatus of claim 10, wherein the container is a glass or other material container allowing desired gas saturation before the process.

12. The apparatus of claim 10, wherein the aerosol generator is a nebulizer, compression sprayer or ultrasonic sprayer.

13. The apparatus of claim 10, further including a carrier gas source, the carrier gas carrying the mist of droplets of the mixture from the aerosol generator to the heating device, and from the heating device to the cooling device.

14. The apparatus of claim 10, wherein the heating device is a furnace or other heat source and heats the droplets in a range of approximately from 100 to 500° C.

15. The apparatus of claim 10, wherein the collecting device comprises a glass or other material cooled collector, cold liquid, solid powder, or solid surface, or combination thereof.

16. The method of controlling the size, shape, quality and the size distribution of nanoparticles by adjusting the length of the reactor, the liquid flow rate through the aerosol generator, the gas flow rate through the reactor, temperature of the reactor and the ratio of components of the reactant mixture.

17. The method of claim 16 where the gas and the liquid flows through the reactors are optimized for the best yield and quality of the product.

18. The method of claim 16, wherein the chemical components controlling the size of nanoparticles are selected from the group consisting of metal precursors, chalcohenide precursors, and surfactants. The ratio of different functional group surfactants can be used to control the size of nanoparticles.

19. The method of claim 16 wherein the size and the size distribution of nanoparticles can be controlled by the ratio of oleic acid to oleylamine, smaller size nanoparticles obtained at higher ratio of oleic acid to oleylamine.

20. The method of claim 21 wherein the ratio of metal precursor to surfactant determines the size of the product: semiconductor nanoparticles, nanometals or nanooxides.
